(19) United States
(12) Patent Application Publication
(10) Pub. No.: US 2006/0220240 A1
(43) Pub. Date: Oct. 5, 2006

(54) Analytic structure for failure analysis of semiconductor device

(75) Inventors: Jong-Hyun Lee, Suwon-si (KR); Hun-Seong Choi, Yeongtong-gu (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/374,579

(22) Filed: Mar. 13, 2006

(30) Foreign Application Priority Data
Mar. 14, 2005 (KR) 2005-21071

(51) Int. Cl. H01L 23/48

(52) U.S. Cl. 257/734

(57) ABSTRACT

An analytic structure includes a plurality of analytic fields formed on a predetermined region of a semiconductor substrate; semiconductor transistors arranged in the analytic fields to compose an array structure, each transistor having a gate electrode and an impurity region; wordlines arranged crosswise on the analytic fields and connecting the semiconductor transistors; and bitline structures connecting the impurity regions of the semiconductor transistors lengthwise, each bitline structure having a bitline and a vertical interconnection structure connecting the bitline with the impurity region. The bitlines have different heights according to their positions on the analytic fields.

### RELATED APPLICATIONS

This application relies for priority on Korean Patent Application No. 2005-21071, filed on Mar. 14, 2005, in the Korean Intellectual Property Office, the contents of which are incorporated herein in their entirety by reference.

### BACKGROUND

1. Field of the Invention

The present invention relates to failure analysis of semiconductor devices and, more particularly, to an analytic structure for failure analysis of semiconductor devices.

2. Discussion of Related Art

Generally, for mass production of a semiconductor device, it is required to secure a stabilized production technology capable of maintaining a profitable yield. A development procedure of the semiconductor device is a series of procedures including a designing procedure, a procedure for a pilot production, and a procedure of testing the pilot-fabricated products, in order to secure the stabilized production technology. Failure analysis is a series of feedback procedures used to determine causes for failures in the pilot-fabricated semiconductor devices and improve them.

In particular, since methods of designing and fabricating the semiconductor device may be changed according to the result of the failure analysis, an adequate failure analysis is very important in the development procedure of the semiconductor device. That is, an erroneous failure analysis can result in wasted time in trials and errors such that a development period of products is delayed. In this point of view, a rapid and accurate failure analysis is very important for securing a short development period and preemption over markets of semiconductor devices.

In general, in order to analyze failures efficiently, test patterns are formed on a semiconductor wafer according to various design rules. Various electrical measurements performed for the test patterns are used for evaluating structural or electrical properties of various micronized electronic devices. For this reason, the test patterns are designed to monitor the structural/electrical properties of elements constituting the semiconductor device.

A fabrication process of the semiconductor device is mainly classified into a front-end process incorporating a plurality of steps carried out until a transistor is formed and a back-end process after the formation of the transistor. Herein, the back-end process is provided with a process of forming an interconnection structure connecting the transistors and a process for forming an interlayer dielectric which plays a role in mechanically supporting and electrically insulating the interconnection structure. U.S. Patent Application No. 2003-034558 (Eiichi Umemura et al.) discloses a technology with regard to an inspection pattern having a contact chain structure in order to evaluate the back-end process. In the disclosure, although it is possible to recognize a fact that failures with regard to interconnections, e.g., failures of interconnections such as short or open, has occurred, it is impossible to obtain detailed information with regard to types or locations of the failures.

In the case of knowing accurate locations of the failures, a portion of a semiconductor substrate corresponding to those locations can be accurately cut off by using a focused ion beam (FIB) or the like and it is possible to enlarge a cut section into a predetermined size for failure analysis through a scanning electron microscope (SEM). However, in the case of not knowing the accurate locations of the failures, a plurality of wafer cutting processes are required for obtaining enlarged visual information which can be used for failure analysis. That is, provided that the failures exist in the cut section during the wafer cutting process, the failures may be enlarged to be capable of being analyzed through the SEM. On the contrary, if there is not accurate information with regard to the locations of the failures, it is not certain whether or not the locations of the failures exist in the cut section. As a result, it may be necessary to carry out the wafer cutting process many times. In particular, in the case of analyzing the semiconductor device having a limited number of failures therein, a wafer specimen may be damaged during an inaccurate wafer cutting process so that it may be impossible to analyze the failures. In this case, since the causes for the failures are not discovered, the development time may be increasingly delayed.

### SUMMARY OF THE INVENTION

An aspect of the present invention is directed to an analytic structure for failure analysis of a semiconductor device. In an exemplary embodiment, the analytic structure may include a plurality of analytic fields formed on a predetermined region of a semiconductor substrate; semiconductor transistors arranged in the analytic fields to compose an array structure, each transistor having a gate electrode and an impurity region; wordlines arranged crosswise on the analytic fields and connecting the semiconductor transistors; and bitline structures connecting the impurity regions of the semiconductor transistors lengthwise, each bitline structure having a bitline and a vertical interconnection structure connecting the bitline with the impurity region. The bitlines have different heights according to their positions on the analytic fields.

In one embodiment, the vertical interconnection structures have different patterns according to the positions of the analytic fields.

In one embodiment, each of the vertical interconnection structures comprises metal pads of at least one layer and plugs of at least one layer, and the layers forming the metal pads and the plugs of the vertical interconnection structure are different in number and pattern according to the positions of the analytic fields. In one embodiment, each of the vertical interconnection structures comprises a multi-via structure in which at least two plugs are connected with one metal pad.

In one embodiment, the semiconductor transistors constitute an SRAM cell array having two load transistors, two driver transistors, and two transfer transistors. In one embodiment, the wordlines connect gate electrodes of the transfer transistors crosswise; and the bitline structure connects the impurity regions, used as drain electrodes of the transfer transistors, lengthwise.

In one embodiment, the analytic structure further comprises a dummy pattern connected to a ground voltage, the dummy pattern being disposed at one side or both sides of the bitline in respective analytic fields to verify whether a bridge is formed between the bitlines.

In one embodiment, in respective analytic fields, the bitline includes at least one proximate portion formed in the close proximity of an adjacent bitline to verify whether a bridge is formed between the bitlines.

### BRIEF DESCRIPTION OF THE DRAWINGS

FIG. 1 illustrates an analytic structure according to an embodiment of the present invention.

FIGS. 2A-10A are top plan views of an analytic structure according to an embodiment of the present invention.

FIGS. 2B-10B are perspective views of the analytic structure according to the present invention, corresponding to FIGS. 2A-10A, respectively.

FIG. 11 is a circuit diagram of a SRAM cell array.

FIGS. 12A-12D illustrate tables of process margins applied to respective process steps, for describing a fabricating method according to the present invention.

FIG. 13 is a failure analysis flowchart for describing a failure analysis method according to the present invention.

### DETAILED DESCRIPTION OF PREFERRED EMBODIMENTS

The present invention will be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. It will also be understood that when a layer is referred to as being “on” another layer or substrate, it can be directly on the other layer or substrate, or intervening layers may also be present.

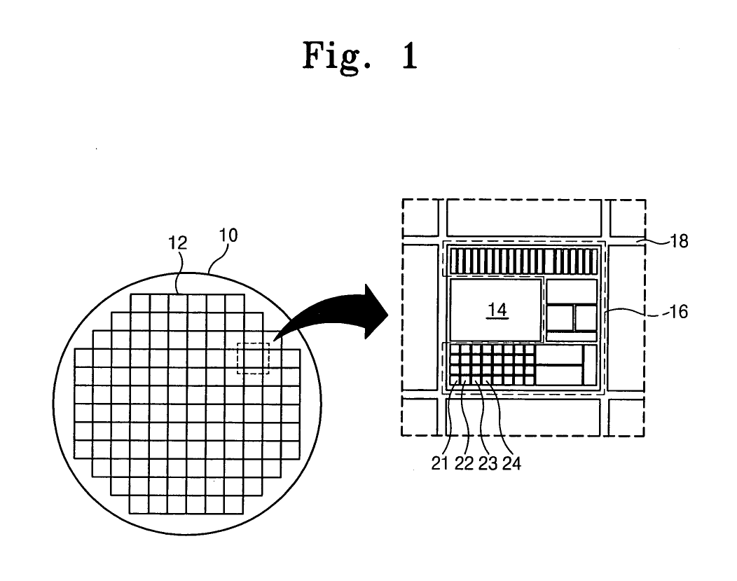

FIG. 1 illustrates an analytic structure according to an embodiment of the present invention.

Referring to FIG. 1, a plurality of dies 12 are disposed in a semiconductor wafer 10. Each of the dies 12 is provided with a product region 14 and auxiliary regions 16. The dies 12 are separated from one another through a wafer sawing process so that they may be used for a semiconductor product. The product region 14 is a region which will be used for the semiconductor product and the auxiliary regions 16 are regions where analytic structures for evaluating appropriateness of a fabrication process are allocated. An area of the auxiliary region 16 becomes reduced when a development procedure for the semiconductor product is changed into a step for mass production. In particular, the auxiliary region 16 may not be allocated inside the die 12 but at a cutting region 18 between the dies 12.

The analytic structure may include test patterns formed according to various design rules to analyze a process method which is capable of securing process stability. More specifically, the analytic structure may include front-end analytic structures for evaluating process stability of a fabrication process for a transistor and back-end analytic structures for evaluating process stability of post processes after the formation of the transistor such as a process of forming an interconnection.

The front-end analytic structures may be provided with transistors of predetermined structures modified by various types. The fabrication process of the transistors constituting the semiconductor product may be optimized by conducting an electrical test of various items for the front-end analytic structures.

Likewise, the back-end analytic structures may be provided with interconnection structures of predetermined structures modified by various types. The process of forming the interconnection structures may be optimized by conducting an electrical test of various items for the back-end analytic structures. In general, the interconnection structures may include a contact plug, a via plug, a metal pattern, a metal line or the like. Accordingly, through a test for the back-end analytic structures, it is possible to determine the causes of the failures generated in processes of forming and patterning interlayer dielectrics, a process of filling plug contact layers, processes of forming and patterning metal layers and so forth.

In order to readily analyze the failures generated in the interconnection structures, the interconnection structures are allocated to connect the transistors of an array structure. As will be described below in detail, horizontal locations of the failures (i.e., locations of cells where the failures are generated) may readily be determined by using the transistor array. In addition, the analytic structures may be configured for independently testing each port of the interconnection structures for use in the semiconductor device. In order to independently test each part, the present invention may include a plurality of interconnection structures having their own configurations that are different from one another. Likewise, as will be fully described below in detail, vertical locations of the failures (i.e., location of layers where the failures are generated) may readily be analyzed using the interconnection structure. According to the present invention, each of the interconnection structures may be allocated at respective auxiliary regions 16.

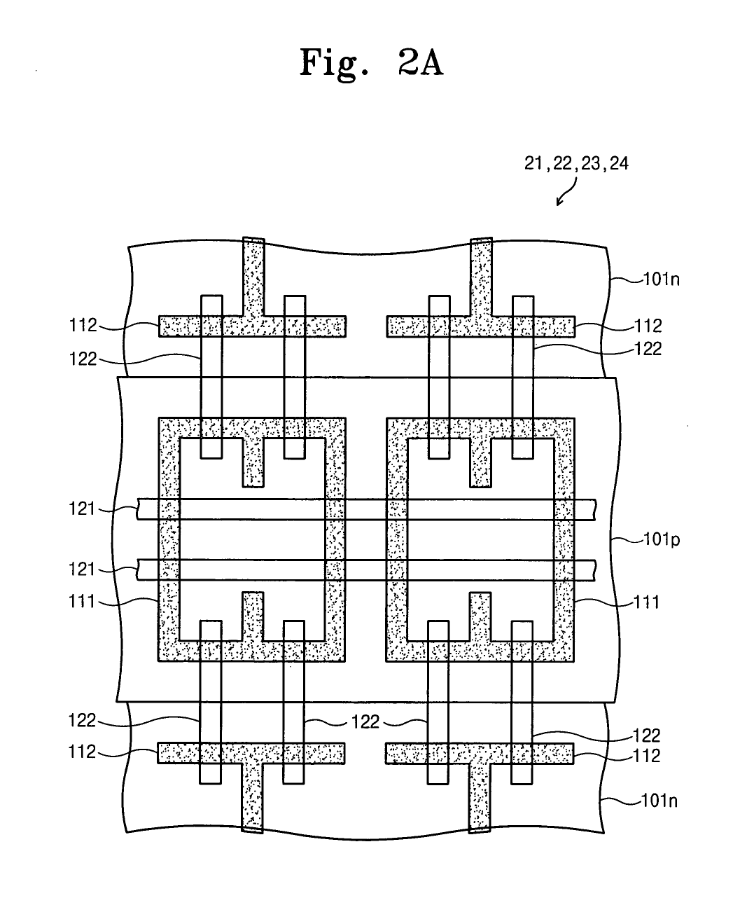

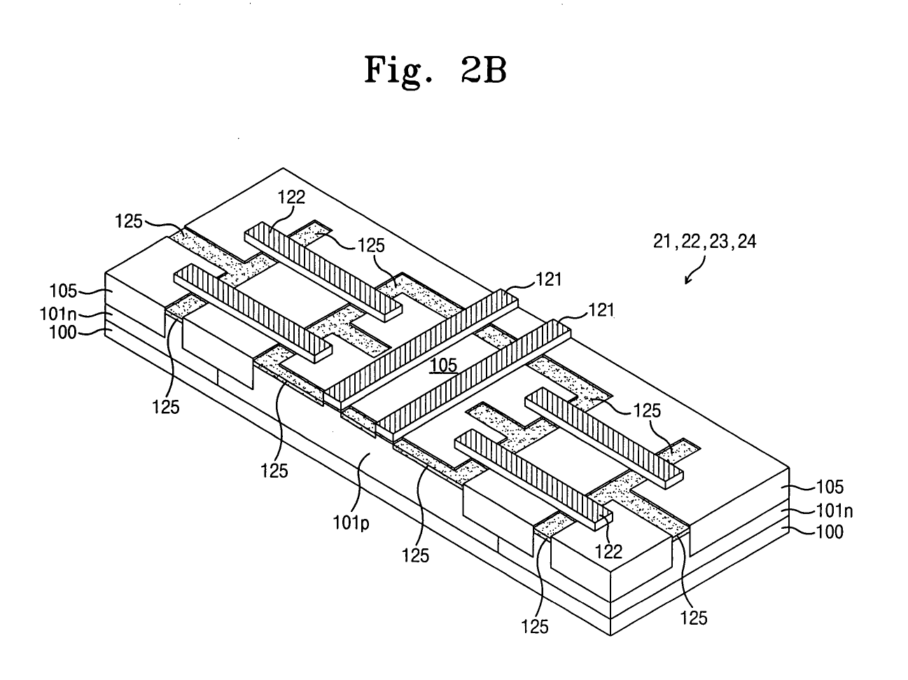

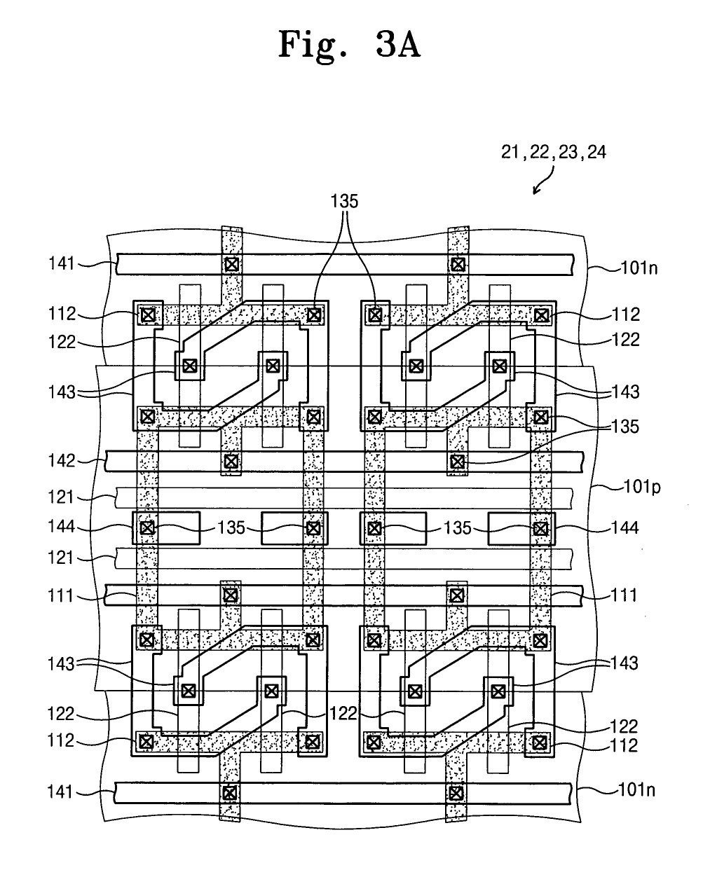

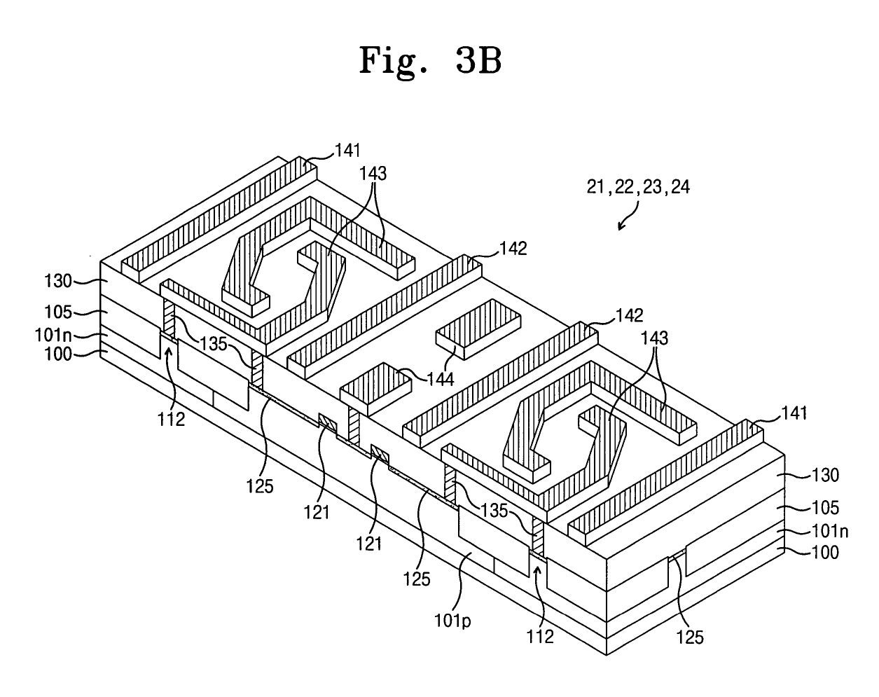

FIG. 2A and FIG. 2B are a top plan view and a perspective view, respectively, of a transistor structure according to an embodiment of the present invention. Further, FIG. 3A and FIG. 3B are a top plan view and a perspective view, respectively, of first metal patterns according to an embodiment of the present invention.

According to the present invention, a plurality of analytic fields are allocated in one die 12, wherein, in general, the number of layers and structure of each analytic field are different from the others. Specifically, the following embodiments are concerned with the back-end analytic structure of a semiconductor device having a first, a second, a third, a fourth, and a fifth metal pattern. In these embodiments, four analytic fields such as a first, a second, a third, and a fourth analytic field 21, 22, 23 and 24 are allocated in one die 12. The number and the structures of the analytic fields are variable with the number of layers constituting the semiconductor device.

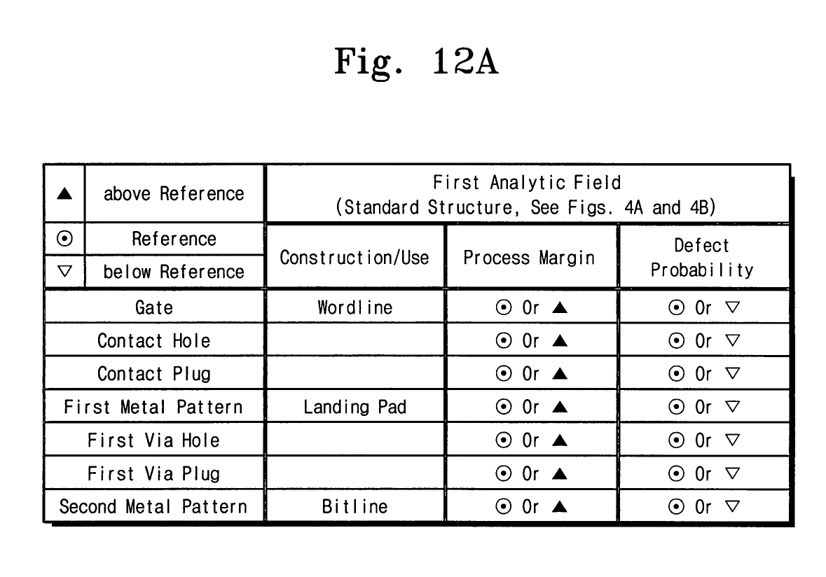

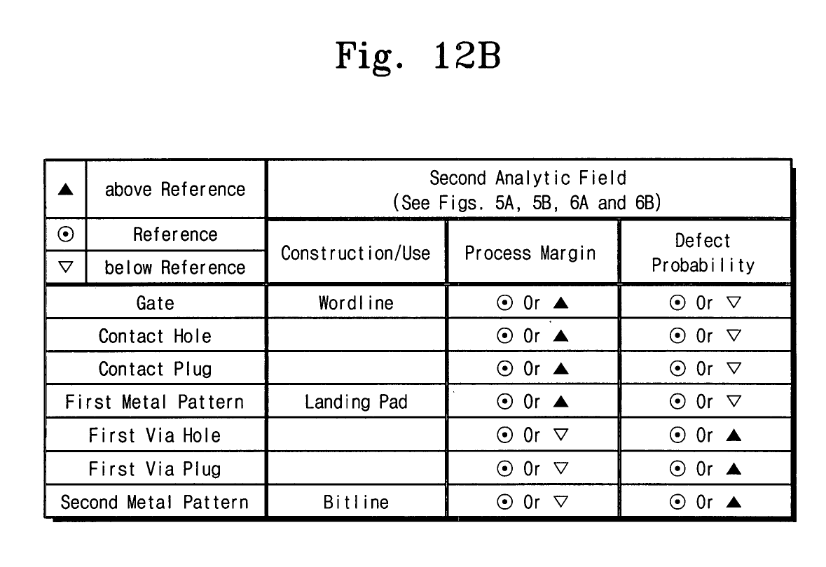

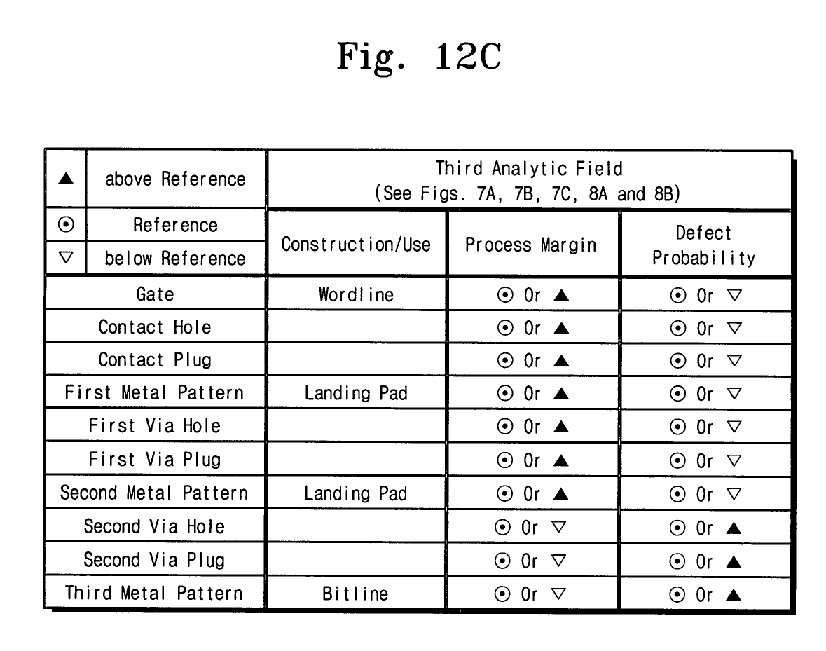

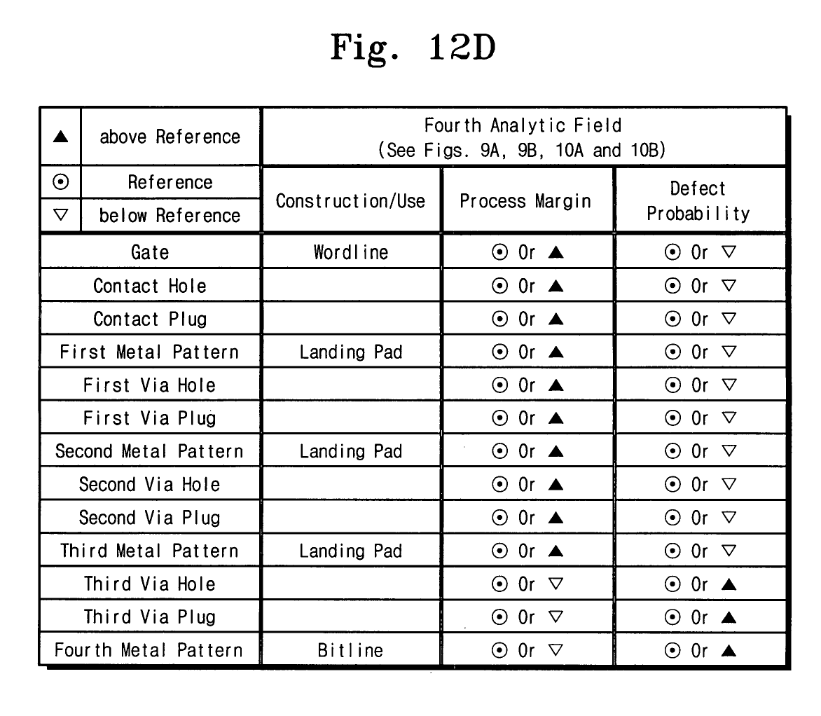

In an exemplary embodiment, the first analytic field 21 is configured for determining the failures generated in the structure of a standard SRAM cell array. Accordingly, the first and second metal patterns in the first analytic field 21 is formed with the design rule having a standard process margin (see FIG. 12A). The process margin means a marginal rate for process conditions to prevent the failures in each unit step. Process defects decrease with increased process margin, while process defects increase with reduction in process margin. Although there are many ways to increase the process margin, the easiest way is to increase a design rule. That is, technical difficulties arising from photolithography, etching, and-deposition processes may readily be overcome by increasing width or area of patterns.

In the other analytic fields 22, 23, and 24, a fabricating process until formation of the first metal pattern is performed with a larger process margin than a standard process margin. In a case where the cell transistors are formed by means of a process having a larger process margin than a standard process margin, process failures generated in the cell transistor may be reduced. Therefore, random failures generated in the second, third, and fourth analytic fields 22, 23, and 24 may be construed as process defects that are not generated in the cell transistors but in the interconnections. In a modified embodiment, the first and second metal patterns in the first analytic field 21 may also be formed with the design rule having the higher process margin than the standard process margin.

The second metal pattern used as a bitline in the first analytic field 21 is formed with the design rule having a larger process margin than a standard process margin, which leads to difficulty in determining failures generated in the second metal pattern in the first analytic field 21. The second analytic field 22 is configured for determining the failures generated in the second metal pattern. In this regard, the second metal pattern in the second analytic filed 22 is formed with the design rule having a smaller process margin than the standard process margin (see FIG. 12B). Since the second metal pattern is used as a bitline in the first and second analytic fields 21 and 22, it is unnecessary to locate the third and fourth metal patterns in these fields 21 and 22. Thus, failures generated in the third and fourth metal patterns may not be determined in the first and second analytic fields 21 and 22.

The third and fourth analytic fields 23 and 24 are configured for determining the failures generated in the third and fourth metal patterns. In this regard, the third metal pattern is formed in the third analytic field 23 with a design rule having a smaller process margin than the standard process margin (see FIG. 12C) and the fourth metal pattern is formed in the fourth analytic field 24 with a design rule having a smaller process margin than the standard process margin (see FIG. 12D). To simplify causes of the failures, a process before formation of an uppermost metal pattern used as a bitline is performed with the design rule having a larger process margin than the standard process margin. For example, the second metal pattern is formed in the third analytic field 23 with the design rule having the larger process margin than the standard process margin, and the second and third metal patterns are formed in the fourth analytic field 24 by the design rule having the larger process margin than the standard process margin.

Although the configurations of respective analytic fields will be described below in detail, they are not limited to these specific configurations, and various modifications and changes may be made without departing from the spirit and scope of the present invention.

FIG. 2A and FIG. 2B are a top plan view and a perspective view, respectively, of a transistor structure according to an embodiment of the present invention. FIG. 3A and FIG. 3B are a top plan view and a perspective view, respectively, of the configuration of first metal patterns according to the present invention. The transistor structure and the first metal patterns all have the same configuration in the four analytic fields 21, 22, 23, and 24.

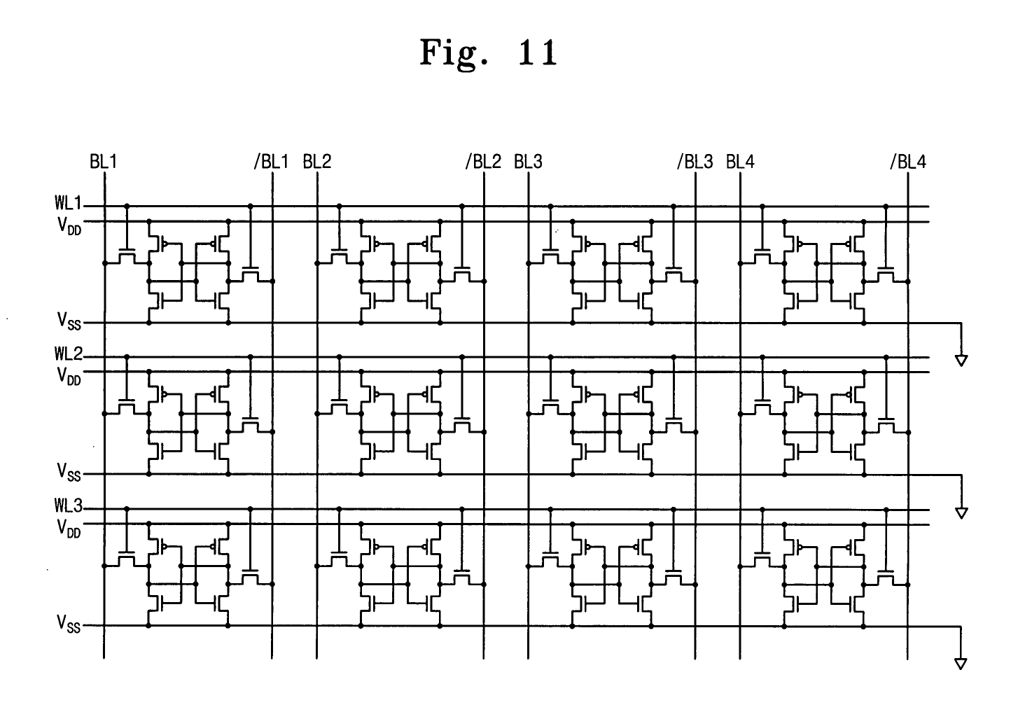

Referring to FIG. 2A and FIG. 2B, the analytic structure has an array structure, including CMOS SRAM cells formed at a semiconductor substrate 100 (see FIG. 11). The CMOS SRAM cell includes a pair of driver transistors, a pair of transfer transistors, and a pair of load transistors.

Device isolation layers 105 are formed at the semiconductor substrate 100 to define first active regions 111 and second active regions 112. The formation of the device isolation layers 105 may be done by means of a conventional isolation technique such as, for example, shallow trench isolation (STI). The first active regions 111 may be shaped in a closed belt having four corners and the second active regions 112 may be patterned in shape of the English character “H”. The device isolation layers 105 are disposed within the first active regions 111 as well as between the first and second active regions 111 and 112.

The driver and transfer transistors are disposed in first active regions 111 while the load transistors are disposed in the second active regions 112. The transfer transistors use a first gate pattern 121, which is arranged to intersect pluralities of cells, as their gate electrodes. The first gate pattern 121 is used as a wordline in the CMOS SRAM cell array. For this, a plurality of the first gate patterns 121 are arranged to cross over the first active region 111 in a plurality of CMOS SRAM cells.

The drive transistors use a second gate pattern 122 as their gate electrodes. The second gate pattern 122 is also used as gate electrodes of the load transistors. That is, the second gate pattern 122 is commonly used for the gate electrodes of the driver and load transistors, for which it is arranged to cross over the first and second active regions 111 and 112.

In the first and second active regions 111 and 112 at opposite sides adjacent to the first and second gate patterns 121 and 122, impurity regions 125 are arranged to be used as source/drain regions of the driver, transfer, and load transistors. The first active region 111 contains a P-type well 101p while the second active region 112 contains an N-type well 101n. The impurity regions 125 are formed to have N-type conductivity in the first active region 111, while they are formed to have P-type conductivity in the second active regions 112. As a result, the driver and transfer transistors are NMOS transistors while the load transistors are PMOS transistors.

Referring to FIG. 3A and FIG. 3B, a first interlayer dielectric 130 is deposited on the resultant structure including the driver, transfer, and load transistors. Contact plugs 135 are formed, being connected to top surfaces of the impurity regions 125 through the first interlayer dielectric 130.

First metal patterns are formed on the interlayer dielectric 130 to connect the contact plugs 135. The first metal patterns are used for power supply voltage (VDD) lines 141, ground voltage (VSS) lines 142, local interconnections 143, and first pads 144. The VDD lines 141 cross over the centers of the second active regions 112, being electrically connected to the impurity regions 125 of the load transistors. The VSS lines 142 cross over the first active regions 111, being electrically connected to the source regions 125 of the driver transistors interposed between the second gate patterns 122. The local interconnections 143 connect the second gate patterns 122 with the impurity regions 125 of the driver and load transistors such that the pairs of drive and load transistors constitute a pair of inverters. The first pads 144 are connected to the impurity regions 125 of the transfer transistors through the contact plugs 135 disposed between the first gate patterns 121.

According to an embodiment of the invention, a second interlayer dielectric 150, a third interlayer dielectric 170, a fourth interlayer dielectric 190, and a fifth interlayer dielectric 150 are sequentially stacked on the resultant structure including the first metal patterns, 141, 142, 143, and 144. The interlayer dielectrics 130, 150, 170, 190, and 210 may be made of silicon oxides or low-k dielectrics. Second metal patterns, 161, 162, 163, 302, and 303 are formed on the second interlayer dielectric 150. Third metal patterns 183, 184, and 313 are formed on the third interlayer dielectric 170. Fourth metal patterns 204 and 324 are formed on the fourth interlayer dielectric 190.

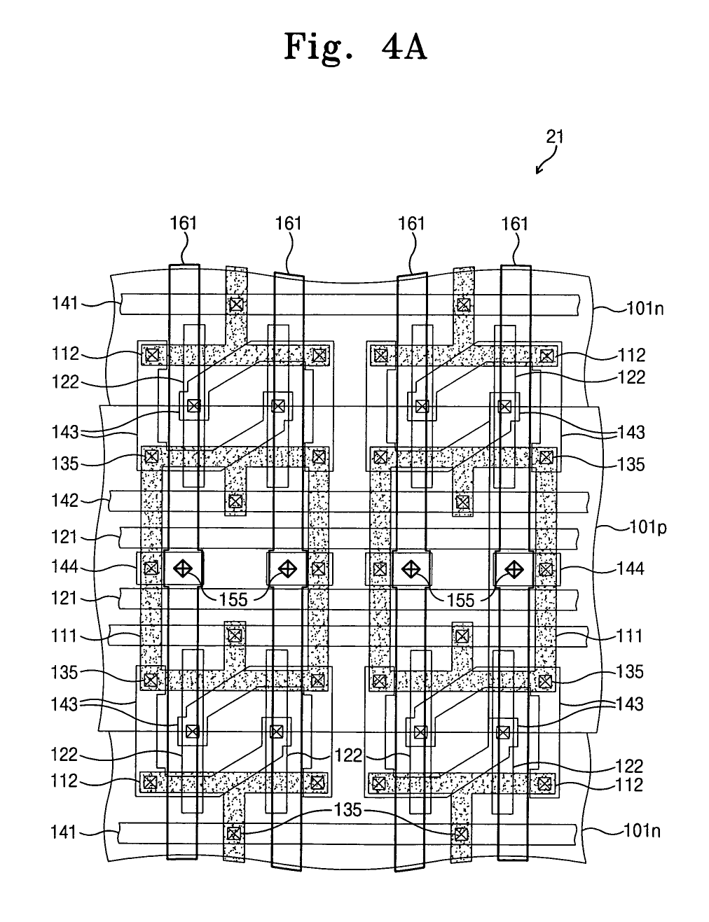

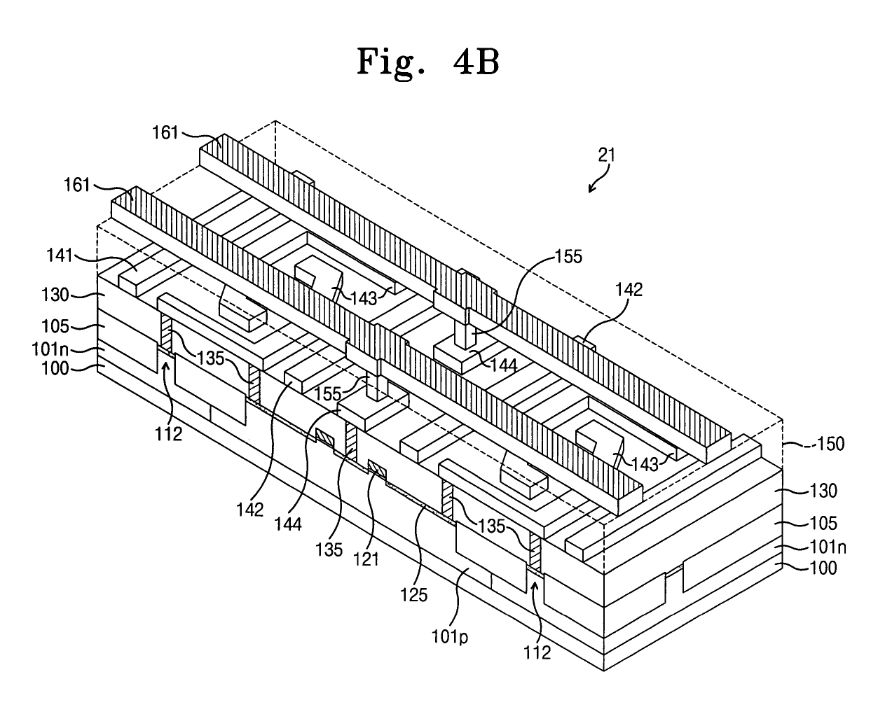

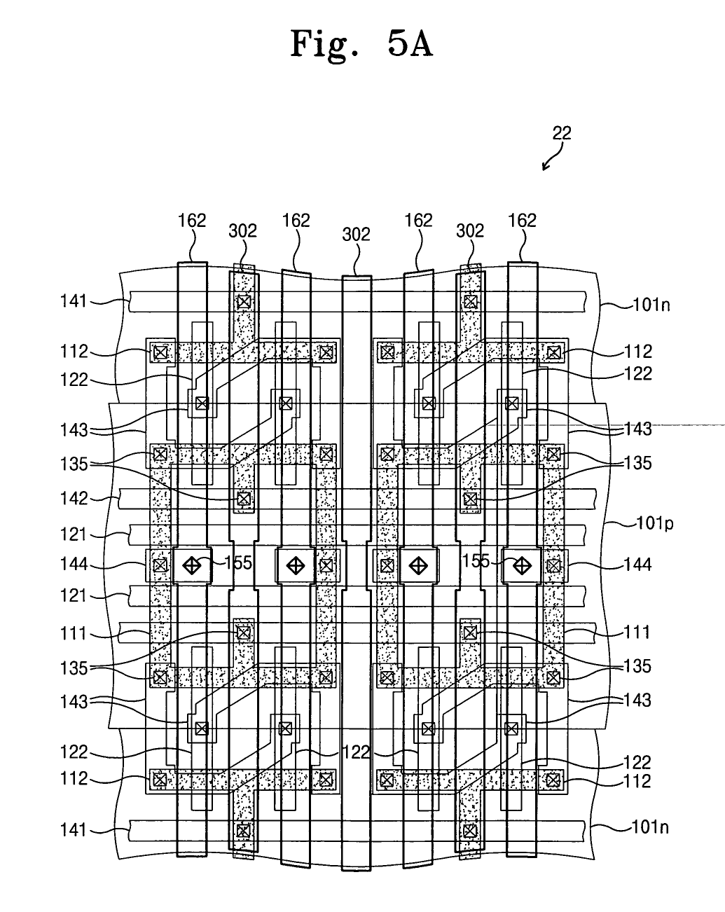

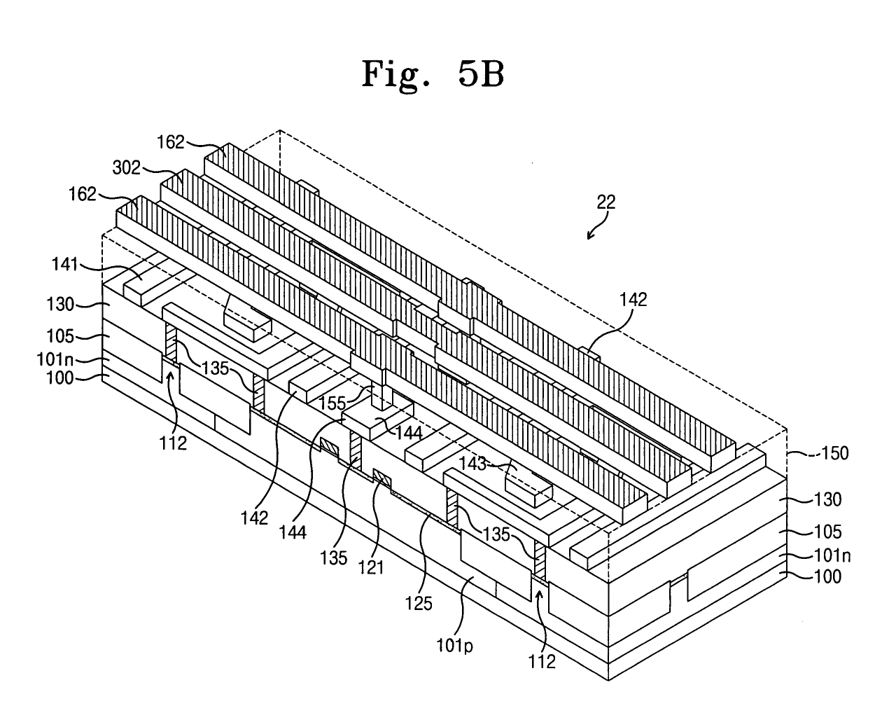

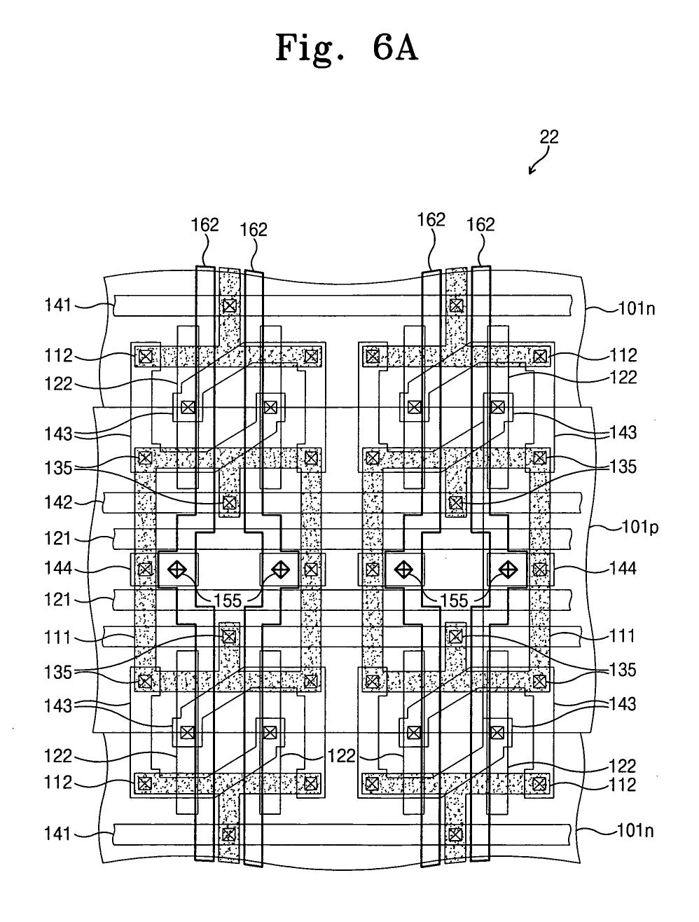

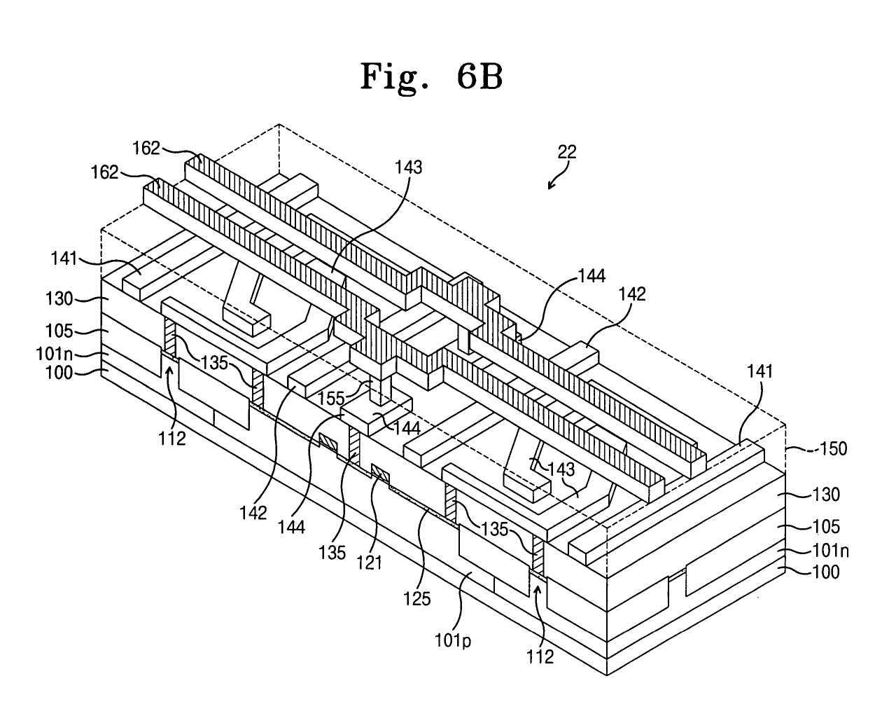

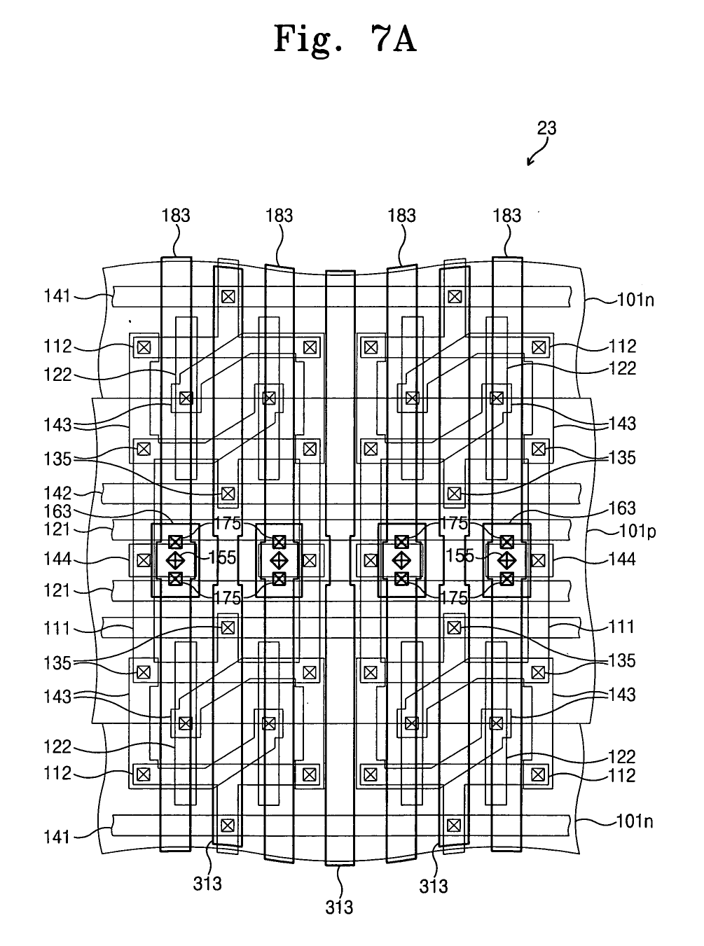

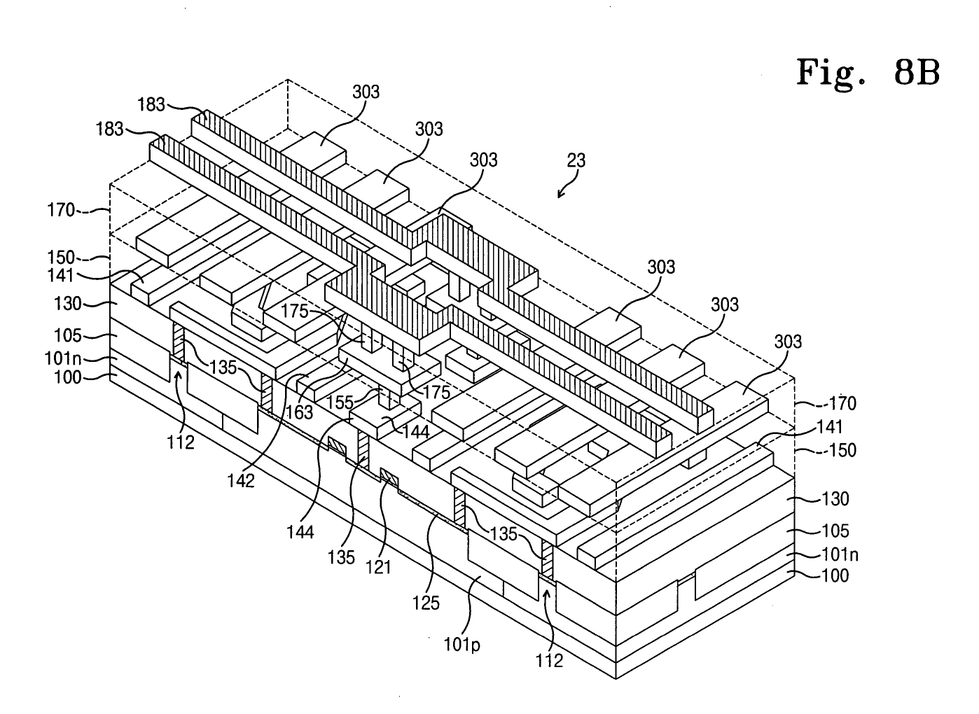

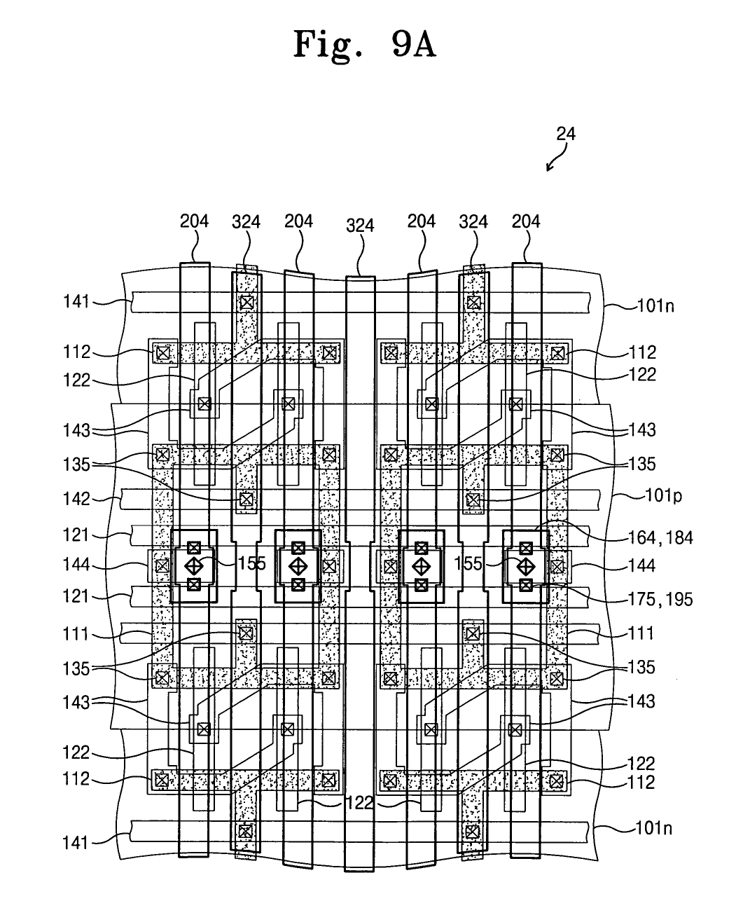

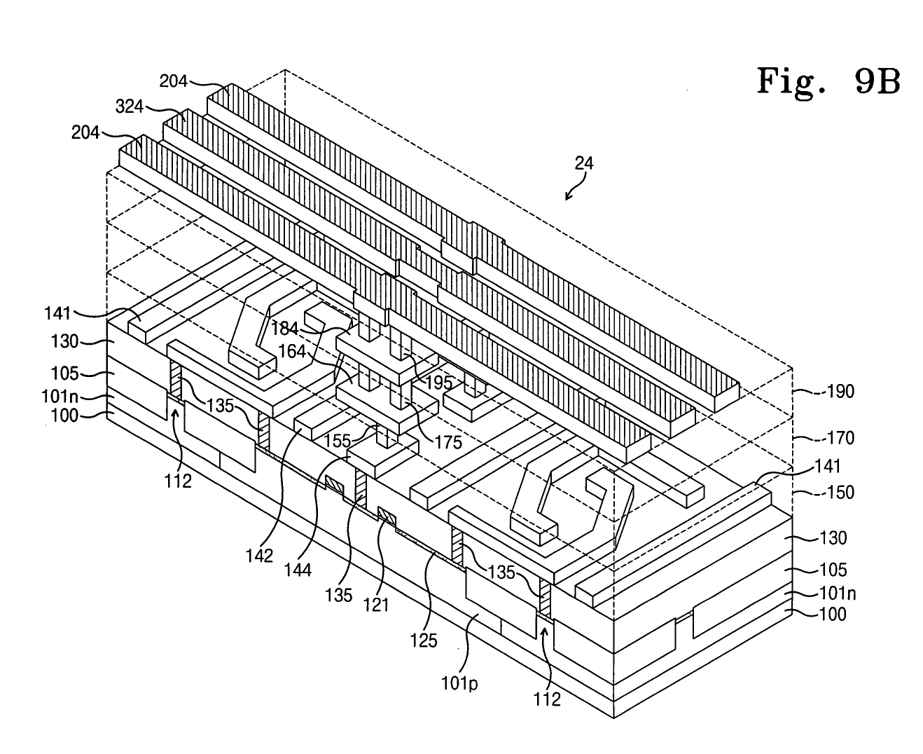

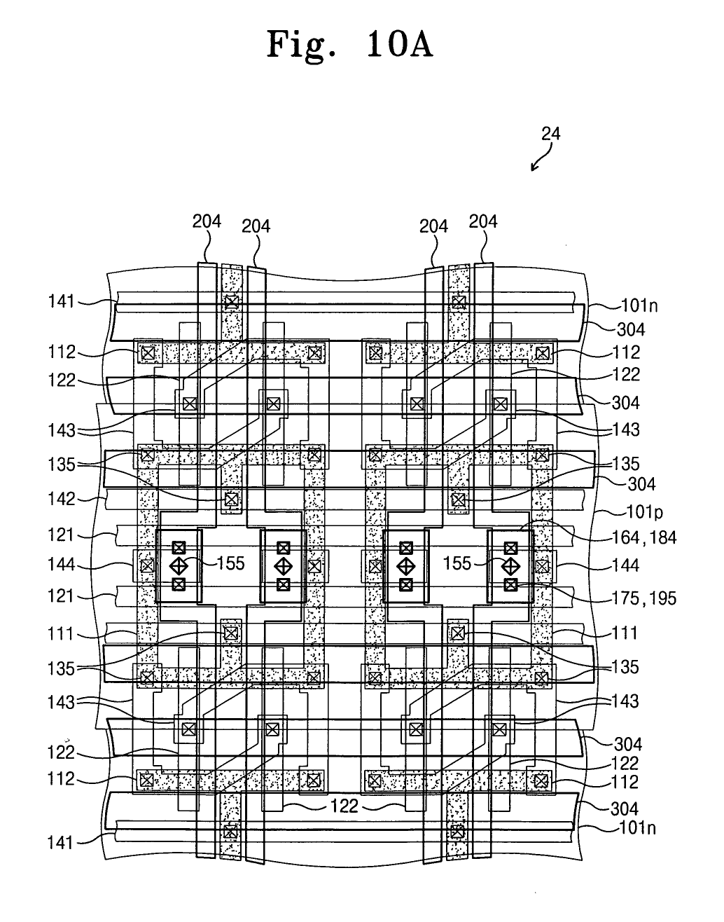

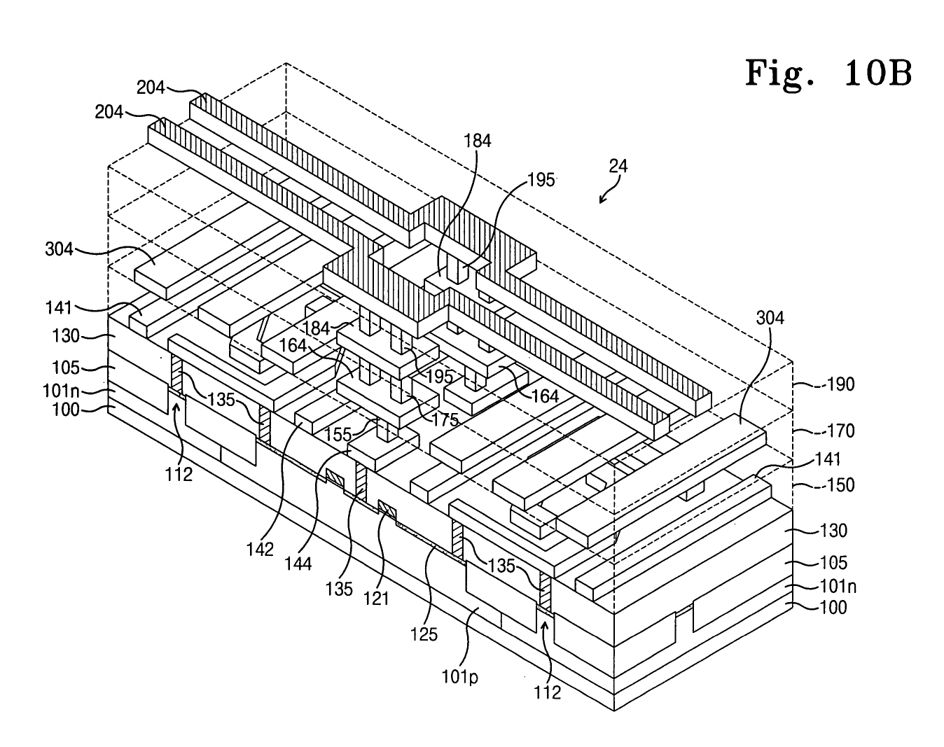

In the first to fourth analytic fields 21, 22, 23, and 24, the second metal patterns 161, 162, 163, and 164 are connected with the first pad 144 through a first via plug 155 penetrating the second interlayer dielectric 150. Nonetheless, uses of the second metal patterns 161, 162, 163, and 164 are variable with the positions of the analytic fields. That is, in the first and second analytic fields 21 and 22, the second metal patterns (161 of FIG. 4B and 162 of FIG. 5B and FIG. 6B) are used as bitlines of an SRAM cell array; and in the third and fourth analytic fields 23 and 24, the second metal patterns (163 of FIG. 7B and FIG. 8B and 164 of FIG. 9B and FIG. 10B) are used as another pad interposed between a bitline (183 of FIG. 7B and FIG. 8B and 204 of FIG. 9B and FIG. 10B) and the first pad 144.

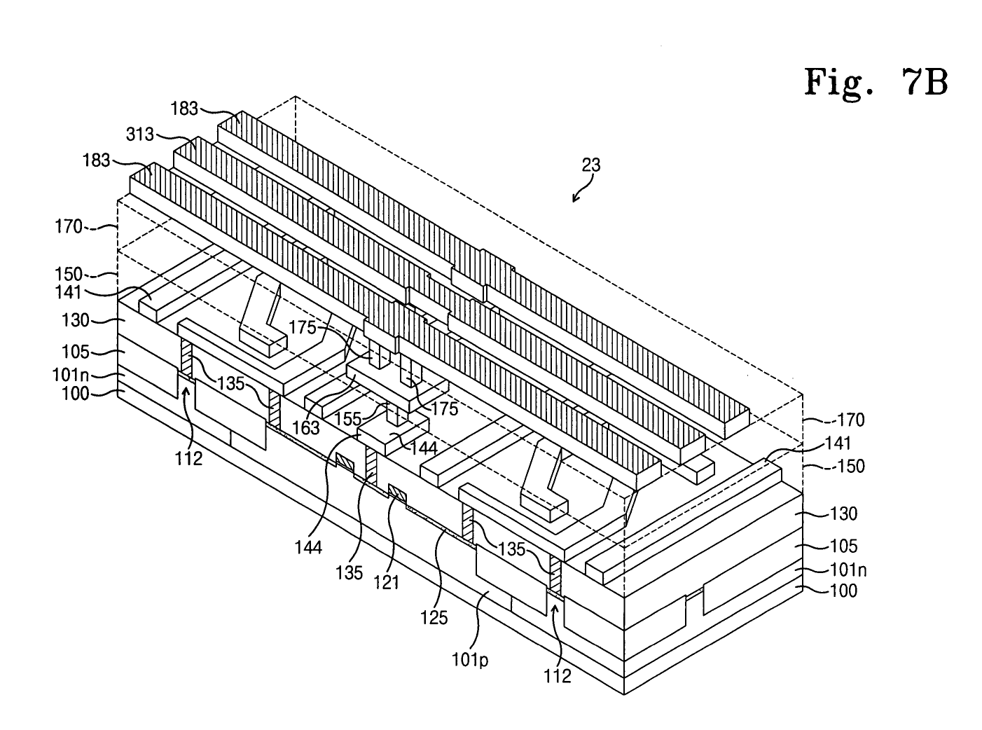

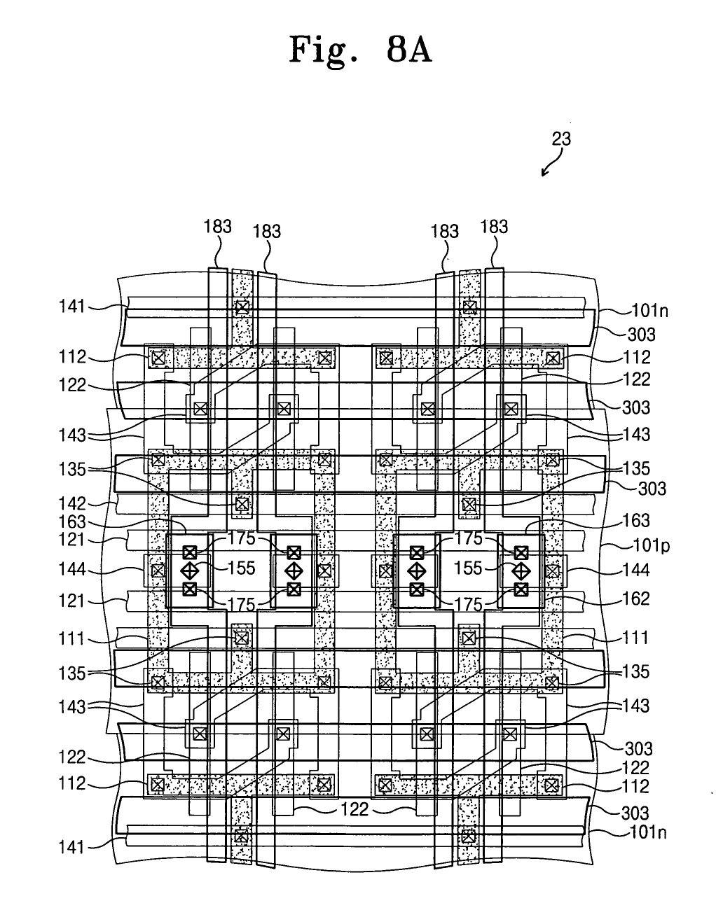

Although the third metal patterns 183 and 184 are connected with the first pad 144 through a second via plug 175 penetrating the third interlayer dielectric 170, their uses are variable with the positions of the analytic field, similar to the second metal patterns. That is, in the third analytic field 23, the third metal pattern (183 of FIG. 7B and FIG. 8B) is used as a bitline for an SRAM cell array; and in the fourth analytic field 24, the third metal pattern (184 of FIG. 9B and FIG. 10B) is used as another pad interposed between a bitline 204 and the second metal pattern 164 used as a pad. As described above, it is unnecessary to locate the third metal patterns 183 and 184 within the first, second, and third analytic fields 21, 22, and 23 in which the second or third metal pattern is used as a bitline.

The fourth metal patterns 204 is connected with the impurity region 125 of the transfer transistor through a third via plug 195 penetrating the fourth interlayer dielectric 190, being used as the bitline of the SRAM cell array. As described above, it is unnecessary to locate the fourth metal patterns 204 within the first, second, and third analytic fields 21, 22, and 23 in which the second or third metal pattern is used as a bitline.

The first, second, and third via plugs 155, 175, and 195 are connected with top surfaces of the first, second, and third metal patterns, respectively. Each of the metal patterns and each of the via plugs may be made of a material selected from tungsten (W), aluminum (Al), titanium nitride (TiN), titanium (Ti), tungsten nitride (WN), tantalum (Ta), tantalum nitride (TaN), and polysilicon.

As described above, the second, third, and fourth metal patterns are formed in the second, third, and fourth analytic fields 22, 23, and 24 with the design rule having a process margin that is equal to or smaller than the standard process margin. In the vicinity of metal patterns used as bitlines, another metal pattern may be disposed closely to realize such a strict design rule. This will be described below in detail with reference to bitline structures according to the present invention.

FIG. 4A and FIG. 4B are a top plan view and a perspective view, respectively, of a first analytic field 21 having a standard bitline structure of a full CMOS SRAM cell array, according to an embodiment of the present invention. Second metal patterns 161 disposed in the second analytic field 21 are connected with the impurity region 125 of the transfer transistor through the first via plug 155, the first pad 144, and the contact plug 135. As a result, the second metal patterns 161 constitute a bitline connecting the SRAM cells (specifically, the transfer transistors) lengthwise. Therefore, the third, fourth, and fifth metal patterns are not needed in the first analytic field 21 any longer.

FIG. 5A and FIG. 5B are a top plan view and a perspective view, respectively, of a bitline structure of a second analytic field 22 according an embodiment of the present invention. Referring to FIG. 5A and FIG. 5B, second metal patterns 162 disposed in the second analytic field 22 have the same configuration as the second metal pattern 161 disposed in the first analytic field 21. As a result, the second metal patterns 162 disposed in the second analytic field 22 constitute bitlines connecting the SRAM cells (specifically, the transfer transistors) lengthwise.

The second analytic field 22 further includes dummy lines 302 disposed between the bitlines 162. The dummy lines 302 are spaced apart from the bitlines 162 to confirm whether a bridge is formed between interconnections formed simultaneously with formation of second metal patterns (i.e., bitline) in the second analytic field 22. If the bridge is formed, electrically connected are two adjacent interconnections that should be electrically insulated from each other. The dummy line 302 is connected with a ground voltage to confirm whether the bridge is formed during a test.

FIG. 6A and FIG. 6B are a top plan view and a perspective view, respectively, of a bitline structure of a second analytic structure 22 according to a modified embodiment of the present invention. In the modified embodiment of FIG. 6A and FIG. 6B, the second metal pattern 162 is close to another adjacent second metal pattern 162 rather than to the dummy line 302 of FIG. 5B to confirm whether the bride is formed. In this regard, the second metal patterns 162 may include portions bent toward each other, as illustrated. The second metal patterns 162 may be used as bitlines of an SRAM cell array, similar to the above-described embodiment.

FIG. 7A and FIG. 7B are a top plan view and a perspective view, respectively, of a bitline structure of a third analytic field 23 according to an embodiment of the present invention. FIG. 9A and FIG. 9B are a top plan view and a perspective view, respectively, of a bitline structure of a fourth analytic field 24 according to an embodiment of the present invention. As described above, a dummy line 302 is disposed between bitlines of the second analytic field to realize a strict design rule, which may be equivalently applied to bitlines of the third and fourth analytic fields 23 and 24. That is, dummy lines (313 of FIG. 7A and FIG. 7B) formed simultaneously with formation of third analytic field 23, and dummy lines (324 of FIG. 9A and FIG.. 9B) formed simultaneously with formation of fourth metal patterns 204 may be disposed between bitlines 204 of the fourth analytic field 24. These dummy lines 313 and 324 are connected with a ground voltage, as described above.

A vertical interconnection structure connecting the bitline 204 with the impurity region 125 may have a double- or multi-via configuration, where the vertical interconnection structure is connected with an underlying metal pattern through at least two via plugs, to secure a larger process margin. For example, two via plugs 175 and 195 are disposed on top surfaces of the second metal pattern 163 used as a pad in the third analytic field 23, the second metal pattern 164 used as a pad in the fourth analytic field 24, and the third metal patterns 184, respectively, to form a double-via configuration.

FIG. 8A and FIG. 8B are a top plan view and a perspective view, respectively, of a bitline structure of a third analytic field 23 according to a modified embodiment of the present invention. FIG. 10A and FIG. 10B are a top plan view and a perspective view, respectively, of a bitline structure of a fourth analytic field 23 according to an embodiment of the present invention. As described above, bitlines of the second analytic field 22 are bent to realize a strict design rule (see FIG. 6A and FIG. 6B), which may be equivalently applied to the bitlines of the third and fourth analytic fields 23 and 24. That is, bitlines 183 of the third analytic field 23 are bent to be close another third metal pattern 183 and bitlines 204 of the fourth analytic field 24 are bent to be close to another fourth metal pattern 204.

Similar to the foregoing embodiments, the interconnection structure according to the modified embodiment may also have a double- or multi-via configuration to secure a larger processing margin. Further, sub-patterns 303 and 304 may be disposed in the vicinity of metal patterns below a bitline to suppress the loading effect in a patterning process.

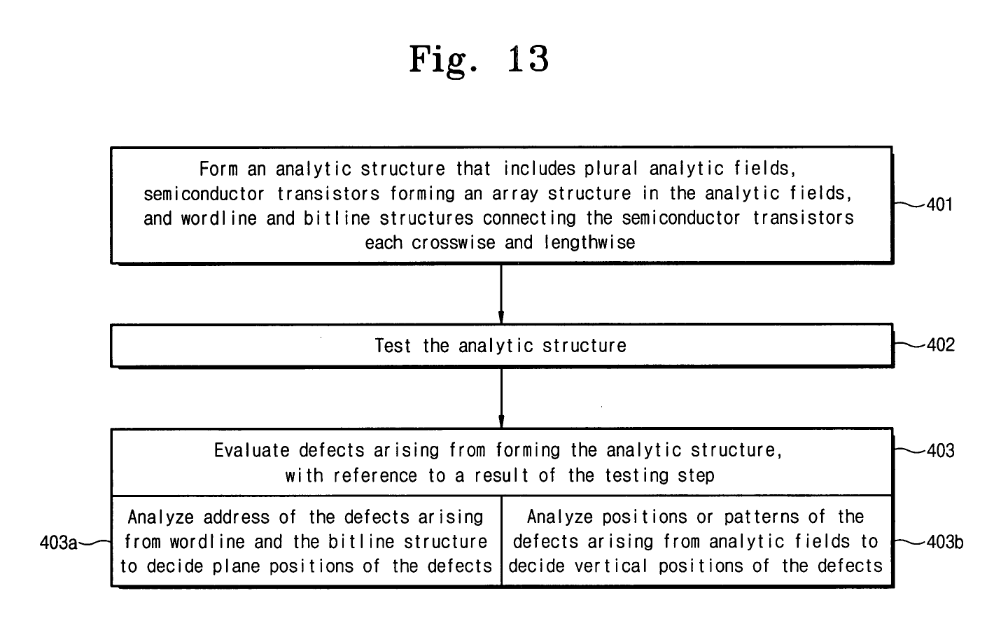

In summary, the interconnection structures disposed in the first, second, third, and fourth analytic fields 21, 22, 23, and 24 have different heights and configurations to analyze respective metal patterns constituting an interconnection structure of a predetermined semiconductor device according to their vertical heights. In the respective fields, a predetermined metal pattern is formed by performing a process-with a process margin that is equal to or smaller than a standard process margin, and the other metal elements are formed by performing a process with a process margin that is larger than the standard process margin. Thus the probability of generating failures may be confined to a process of forming the predetermined metal pattern, which makes it possible to readily determine a vertical position of the failure (see 403b of FIG. 13).

A plane position of failure is readily obtained from an address where the failure is generated. The address of the failure may be readily determined by detecting positions of wordlines and bitlines where the failure is generated in each analytic field (see 403b of FIG. 13). For example, a predetermined memory test is conducted by connecting a predetermined memory tester with the wordlines and the bitlines to make a failure map that notes plane positions of failures. If the addresses of the failure positions are known, the semiconductor substrate may be cut out at correct positions by means of focused ion beam (FIB). In this case, a sample wafer having a small number of defects is damaged to reduce factors of frustrating failure analysis.

According to the embodiment of the present invention, cell arrays in the analytic fields 21, 22, 23, and 24 include full-CMOS SRAM cell transistors. Therefore, defective patterns may be readily determined from the unique structure of the SRAM cell array. That is, when the failure map denotes all cells connected with a predetermined bitline as cell in failure, it may be concluded that the bitline is open or short-circuited. Further, when the failure map denotes all cells connected with a predetermined wordline as cells in failure, it may be concluded that a defect (especially, open) involved in the first gate pattern 121 arises. If there are defects arising from the contact plug 155, the active regions 111 and 112 or the second gate patterns 122, such defects appear as so-called random 1-bit pattern defects. To verify the presence of the defects, it is necessary to obtain visual information on plane positions of sections containing defects. The visual information may be readily obtained using the array addresses.

If layers constituting an interconnection structure increase in number, it is difficult to find out a vertical position of defect. Therefore, a failure analysis scheme according to the present invention is advantageously available in analyzing scheme defects of the interconnection structure in a semiconductor device, such as a central processing unit (CPU), having many layers of metal patterns. That is, such a CPU may be constructed in the product region (14 of FIG. 1) and vertical and plane positions of defects arising from interconnection constituting the CPU may be readily found out by conducting a test for the analytic fields. There may be variations in process margins and structures of the analytic fields.

According to the present invention, it is possible to determine topological positions (plane and vertical positions) of defects arising from a semiconductor device with multi-level interconnections. Thus analysis for interconnection defects is conducted quickly and accurately. As a result, time required for developing semiconductor devices is shortened.

FIG. 11 is a circuit diagram of a SRAM cell array incorporating the failure analysis approach of the invention.

FIGS. 12A-12D illustrate tables of process margins applied to respective process steps, for describing a fabricating method according to the present invention.

FIG. 13 is a failure analysis flowchart for describing a failure analysis method according to the present invention. According to the method, in step 401, an analytic structure according to the invention having plural analytic fields is formed. Semiconductor transistors forming an array structure are formed in the analytic fields. Wordline and bitline structures connecting the semiconductor transistors crosswise and lengthwise are also formed.

In step 402, the analytic structure is tested.

In step 403, defects arising from forming the analytic structure are evaluated with reference to a result of the testing step. In step 403a, the address of the defects arising from the wordline and bitline structures are analyzed to determine plane positions of the defects. In step 403b, positions or patterns of the defects arising from analytic fields are analyzed to determine positions of the defects.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. An analytic structure for failure analysis of a semiconductor device, comprising:
a plurality of analytic fields formed on a predetermined region of a semiconductor substrate;
semiconductor transistors arranged in the analytic fields to compose an array structure, each transistor having a gate electrode and an impurity region;
wordlines arranged crosswise on the analytic fields and connecting the semiconductor transistors; and
bitline structures connecting the impurity regions of the semiconductor transistors lengthwise, each bitline structure having a bitline and a vertical interconnection structure connecting the bitline with the impurity region,
wherein the bitlines have different heights according to their positions on the analytic fields.

2. The analytic structure of claim 1, wherein the vertical interconnection structures have different patterns according to positions of the analytic fields.

3. The analytic structure of claim 1, wherein each of the vertical interconnection structures comprises metal pads of at least one layer and plugs of at least one layer, and the layers forming the metal pads and the plugs of the vertical interconnection structure are different in number and pattern according to positions of the analytic fields.

4. The analytic structure of claim 3, wherein each of the vertical interconnection structures comprises a multi-via structure in which at least two plugs are connected with one metal pad.

5. The analytic structure of claim 1, wherein the semiconductor transistors constitute an SRAM cell array having two load transistors, two driver transistors, and two transfer transistors.

6. The analytic structure of claim 5, wherein the wordlines connect gate electrodes of the transfer transistors crosswise; and
wherein the bitline structure connects the impurity regions, used as drain electrodes of the transfer transistors, lengthwise.

7. The analytic structure of claim 1, further comprising a dummy pattern connected to a ground voltage, the dummy pattern being disposed at one side or both sides of the bitline in respective analytic fields to verify whether a bridge is formed between the bitlines.

8. The analytic structure of claim 1, wherein in respective analytic fields, the bitline includes at least one proximate portion formed in the close proximity of an adjacent bitline to verify whether a bridge is formed between the bitlines.
